(19) United States
(12) Patent Application Publication
(10) Pub. No.: US 2015/0212432 A1
(43) Pub. Date: Jul. 30, 2015

(54) Reticle Heater to Keep Reticle Heating Uniform

(71) Applicants: ASML NETHERLANDS B.V., Veldhoven (NL); ASML HOLDING N.V., Veldhoven (NL)

(72) Inventors: Johannes Onvlee, 's-Hertogenbosch (NL); Christopher J. Mason, Newtown, CT (US); Earl William Ebert, Oxford, CT (US); Peter A. Delmastro, New Milfort, CT (US)

(73) Assignees: ASML Netherlands B.V., Veldhoven (NL); ASML Holding N.V., Veldhoven (NL)

(21) Appl. No.: 14/429,340

(22) PCT Filed: Aug. 26, 2013
(86) PCT No.: PCT/EP2013/067615

§ 371 Date: Mar. 18, 2015

Related U.S. Application Data
(60) Provisional application No. 61/705,426, filed on Sep. 25, 2012.

(51) Int. Cl. G03F 7/20

(52) U.S. Cl. CPC G03F 7/70875

(57) ABSTRACT

Systems and methods are disclosed for controlling the heating of a reticle. In one embodiment, a plurality of radiation sources generates a plurality of radiation beams (206) and delivers them to a patterning device (210) that absorbs a portion of the radiation from the beams and develops a spatially dependent heating profile. In a further embodiment, a plurality of resistive heating sources (906) generates heat in response to an applied voltage or current. The generated heat is absorbed by the patterning device from the resistive heating sources and leads to the development of a spatially dependent heating profile. Thermal stresses, strains, and deformations can be controlled by controlling the spatially dependent heating profile.

### CROSS-REFERENCE TO RELATED APPLICATIONS

This application claims the benefit of U.S. provisional application 61/705,426, which was filed on 25 Sep. 2012, and which is incorporated herein in its entirety by reference.

### FIELD

The present disclosure relates to a lithographic apparatus and a method for manufacturing a device.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

### SUMMARY

In the present art, problems arise due to heating of the reticle due to absorption of exposure light. It is desirable to have a system that circumvents problems associated with reticle heating that can occur due to absorption of exposure light in a chrome-layer of the reticle and/or in the reticle body during exposure.

According to an aspect of the invention, there is provided an optically based heating system, comprising a plurality of radiation sources a plurality of radiation sources configured to generate a plurality of radiation beams to heat a patterning device at least one of prior to exposing the patterning device and during exposure of the patterning device, and a controller to modulate intensity of radiation from the plurality of radiation sources in at least one of time and a plane substantially perpendicular to the radiation beam in operational use of the patterning device for producing a desired heat pattern in the patterning device by maintaining a constant temperature profile across the patterning device.

In an embodiment there is provided a plurality of optical systems configured to receive the respective radiation beams from the sources and to deliver the radiation beams to the patterning device, and an array of thermal sensors to determine a temperature distribution of the patterning device.

In a further embodiment, a plurality of resistive heating sources each configured to generate heat in response to an applied voltage or current and to deliver the heat to a patterning device at least one of prior to exposing the patterning device and during exposure of the patterning device. A control system is configured to provide a current and/or voltage to at least one of the resistive heating sources. The control system is configured to modulate intensity of radiation from the plurality of resistive heating sources in at least one of time and a plane substantially perpendicular to the radiation beam in operational use of the patterning device for producing a desired heat pattern in the patterning device by maintaining a constant temperature profile across the patterning device.

In a further embodiment, a lithographic apparatus is disclosed. The lithographic apparatus comprises an illumination system, a support, a patterning device, a heating device, a substrate table and a projection system. The illumination system is configured to condition a radiation beam. The support is constructed to support a patterning device. The patterning device is configured to impart the radiation beam with a pattern in its cross-section to form a patterned radiation beam. The heating device is configured to introduce a spatially dependent heating profile to the patterning device. The substrate table is constructed to hold a substrate, and the projection system is configured to project the patterned radiation beam onto a target portion of the substrate.

The controller can be further configured to change the intensity of the radiation of the plurality of radiation sources based on at least one of the sensed thermal distribution of the patterning device and a thermal pattern in which the heat flux into and out of the patterning device reaches a balance.

Further features and advantages as well as the structure and operation of various embodiments are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings which are incorporated herein and form a part of the specification, illustrate the present invention and together with the description, further serve to explain the principles of the invention and to enable a person skilled in the pertinent art(s) to make and use the invention.

FIG. 1 depicts a lithographic apparatus according to an embodiment of the invention.

FIG. 2 provides a schematic illustration of an example system comprising reticle heating, according to an embodiment.

FIG. 3 illustrates a top-down view of an example system comprising reticle heating, according to an embodiment.

FIG. 4 illustrates a further example system including an array of thermal sensors, according to an embodiment.

FIG. 5 schematically illustrates a reticle on a reticle stage during exposure with the resulting development of a thermal profile, according to an embodiment.

FIG. 6 shows a development of a steady state heat profile, according to an embodiment.

FIG. 7 illustrates a reticle pre-heater system, according to an embodiment.

FIG. 8 illustrates a development of a steady state heat profile of the reticle in the pre-heater, according to an embodiment.

FIG. 9 illustrates a further example system including a spatial distribution of thermal heaters, according to an embodiment.

FIG. 10 illustrates the development of a complex thermal profile using a system having a heater array, according to an embodiment.

Embodiments are described below with reference to the accompanying drawings. In the drawings, generally, like reference numbers indicate identical or functionally similar elements. Additionally, the left most digit(s) of a reference number generally identifies the drawing in which the reference number first appears.

### DETAILED DESCRIPTION

A lithographic apparatus and a method for manufacturing a device are disclosed, comprising embodiments that circumvent problems associated with reticle heating.

It is noted that references in this specification to “one embodiment,” “an embodiment,” “an example embodiment,” etc., indicate that the embodiment described may include a particular feature, structure, or characteristic, but not every embodiment may necessarily include the particular feature, structure, or characteristic. Moreover, such phrases are not necessarily referring to the same embodiment. Further, when a particular feature, structure, or characteristic, is described in connection with an embodiment, it is submitted that it is within the knowledge of one skilled in the art to effect such feature, structure, or characteristic in connection with other embodiments whether or not explicitly described. The following detailed description refers to the accompanying drawings that illustrate the example embodiments. The detailed description is not meant to be limiting. Rather, the scope of embodiments is defined by the appended claims.

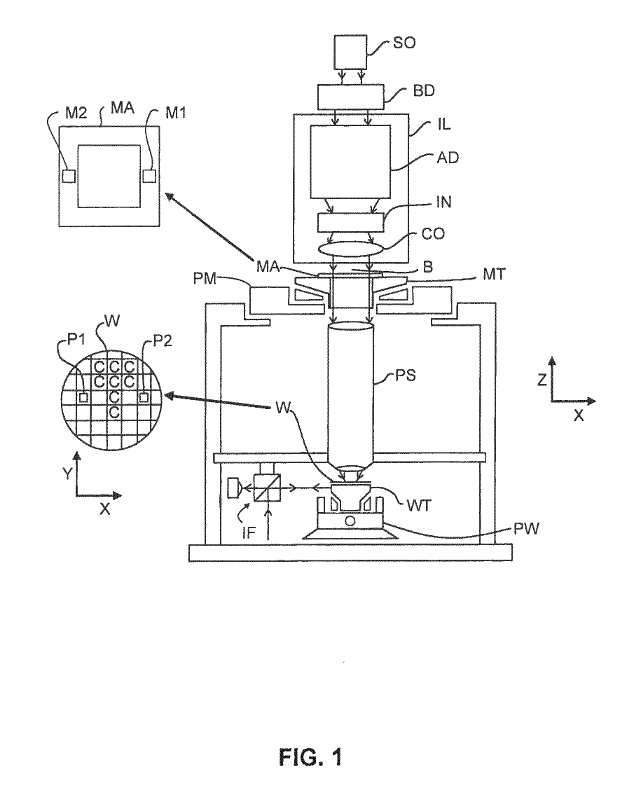

FIG. 1 schematically depicts a lithographic apparatus according to one embodiment of the invention. The apparatus comprises:

an illumination system (illuminator) IL configured to condition a radiation beam;

a support structure (e.g., a mask table) MT constructed to support a patterning device (e.g., a mask) MA and connected to a first positioner PM configured to accurately position the patterning device in accordance with certain parameters;

a substrate table (e.g., a wafer table) WT constructed to hold a substrate (e.g., a resist-coated wafer) W and connected to a second positioner PW configured to accurately position the substrate in accordance with certain parameters; and

a projection system (e.g., a refractive projection lens system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable minor array employs a matrix arrangement of small mirrors, each of which can be individually tilted so as to reflect an incoming radiation beam in different directions. The tilted minors impart a pattern in a radiation beam which is reflected by the minor matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable minor array of a type as referred to above, or employing a reflective mask).

The lithographic apparatus may be of a type having two (dual stage) or more substrate tables (and/or two or more mask tables). In such “multi-stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross section.

The radiation beam B is incident on the patterning device (e.g., mask MA), which is held on the support structure (e.g., mask table MT), and is patterned by the patterning device. Having traversed the mask MA, the radiation beam B passes through the projection system PS, which focuses the beam onto a target portion C of the substrate W. With the aid of the second positioner PW and position sensor IF (e.g., an interferometric device, linear encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies.

The depicted apparatus could be used in at least one of the following modes:

1. In step mode, the mask table MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed. In step mode, the maximum size of the exposure field limits the size of the target portion C imaged in a single static exposure.

2. In scan mode, the mask table MT and the substrate table WT are scanned synchronously while a pattern imparted to the radiation beam is projected onto a target portion C (i.e., a single dynamic exposure). The velocity and direction of the substrate table WT relative to the mask table MT may be determined by the (de-)magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In another mode, the mask table MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable minor array of a type as referred to above.

Combinations and/or variations on the above described modes of use or entirely different modes of use may also be employed.

The following discussion presents embodiments that circumvent problems associated with reticle heating that can occur due to absorption of exposure light in a chrome-layer of the reticle and/or in the reticle body during exposure of a lot. The amount of heat that is absorbed depends on the degree of transmission of the reticle. If no active reticle cooling is applied, reticle temperatures can increase by nearly 6° C. relative to ambient temperatures.

As light is absorbed by the reticle, thermal stresses can develop and thermal expansion can occur. Thermal gradients and stresses can develop due to the relatively low thermal conductivity of the quartz material of typical reticles. Such stresses can lead to local reticle deformations due to the fact that the reticle is typically clamped. Part of this deformation can be corrected through the use of scanning lens elements. Even in such situations, however, a non-correctable error can remain. The remaining error, however, may be too large for future systems with extreme overlay specifications. Thus new embodiments are desired to overcome such problems associated with reticle heating.

In a first embodiment method, heat is added to a part of the reticle that typically does not encounter exposure light. In this way the entire reticle may slowly get warmer as the exposure process proceeds. In this way, thermal gradients, stresses, and deformations can be minimized. As a result, infra-red (IR) light is introduced on a surface of the reticle during scanning and exposure in one or more areas that typically do not encounter exposure light. The intensity of the IR light can be modulated in time and space, so that the correct amount of heat can be introduced on a desired location of the reticle.

By allowing the entire reticle to heat up uniformly, thermal gradients are reduced. Thermal stresses can still develop, however, due to the fact that the reticle is typically clamped. These stresses can be relieved periodically by unclamping the reticle and allowing the reticle to relax. Upon relieving the stress in this way, the reticle can be re-clamped and re-aligned as needed.

This method allows the temperature distribution in the reticle to be maintained to have a nearly uniform spatial distribution. With such a temperature distribution, the resulting reticle deformation comprises a simple magnification that can be trivially corrected without the use of complicated systems including, for example, lens manipulators. Any remaining small non-homogeneous thermal distribution (and corresponding non-homogeneous thermal expansion/deformation) can be compensated for with existing reticle heating solutions.

IR light with wavelength of the order of 1500 nm, 2000 nm, and higher, can be absorbed in quartz materials of typical reticles and can thus be used in various embodiments of the present invention to generate heat. One advantage of this approach is that it does not rely on the presence of an absorber (e.g., the Cr layer) outside of the imaging area.

An optically based heating system, comprising a plurality of radiation sources a plurality of radiation sources configured to generate a plurality of radiation beams to heat a patterning device at least one of prior to exposing the patterning device and during exposure of the patterning device, and a controller to modulate intensity of radiation from the plurality of radiation sources in at least one of time and a plane substantially perpendicular to the radiation beam in operational use of the patterning device for producing a desired heat pattern in the patterning device by maintaining a constant temperature profile across the patterning device.

In an embodiment there is provided a plurality of optical systems configured to receive the respective radiation beams from the sources and to deliver the radiation beams to the patterning device, and an array of thermal sensors to determine a temperature distribution of the patterning device.

The controller can be further configured to change the intensity of the radiation of the plurality of radiation sources based on at least one of the sensed thermal distribution of the patterning device and a thermal pattern in which the heat flux into and out of the patterning device reaches a balance.

In an embodiment, the radiation sources may comprise multiple lasers to deliver IR light to multiple points on the reticle surface. In a further embodiment, a single high-power laser can be used. In the single-laser embodiment, beam splitters and optical switches can be used to generate multiple light beams to deliver IR light as needed. Laser light can be transported from the laser source to the reticle via optical fibers and can be directed to various points on the reticle surface by means of mirrors or optical switches.

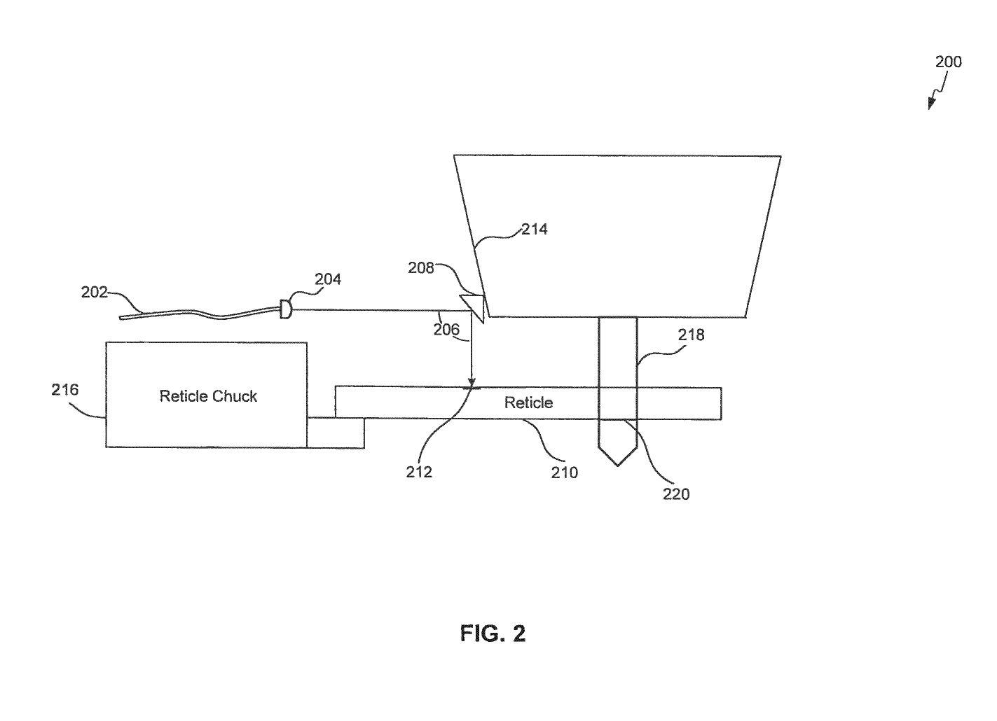

FIG. 2 provides a schematic illustration of an example system 200 according to an embodiment. In this example, optical fibers 202 transport light from lasers (not shown) to optics 204 that are configured to project/focus a beam 206 via a minor 208 (or other optical device) onto a reticle 210. Some of the IR radiation will be absorbed on a top surface 212 of the reticle 210. The absorbed radiation generates heat. The mirror 208 and optics 204 can be installed in a fixed frame (“fixed world”) 214 of the illuminator.

A reticle stage/chuck 216 can move reticle 210 under an exposure beam 218 that is used to expose an image on the reticle. The exposure beam 218 can be absorbed in the chrome layer 220 at the bottom of the reticle.

IR lasers can be modulated in such a way that beam 206 introduces energy 212 only where needed, for instance only outside the image area. The laser light can be modulated in various ways. For example, in addition to on/off modulations, the pulse width and intensity per pulse can be modulated to provide more precise energy control.

The beam 206 can be controlled in terms of position, intensity, and modulation so that a desired amount of energy (heat) can be introduced depending on the absorption profile of a particular reticle. Such beam control can be calibrated or estimated by means of transmission data and a model. Dynamic control can also be obtained using feedback during the exposure/heating process using existing thermal sensors in the reticle stage 216.

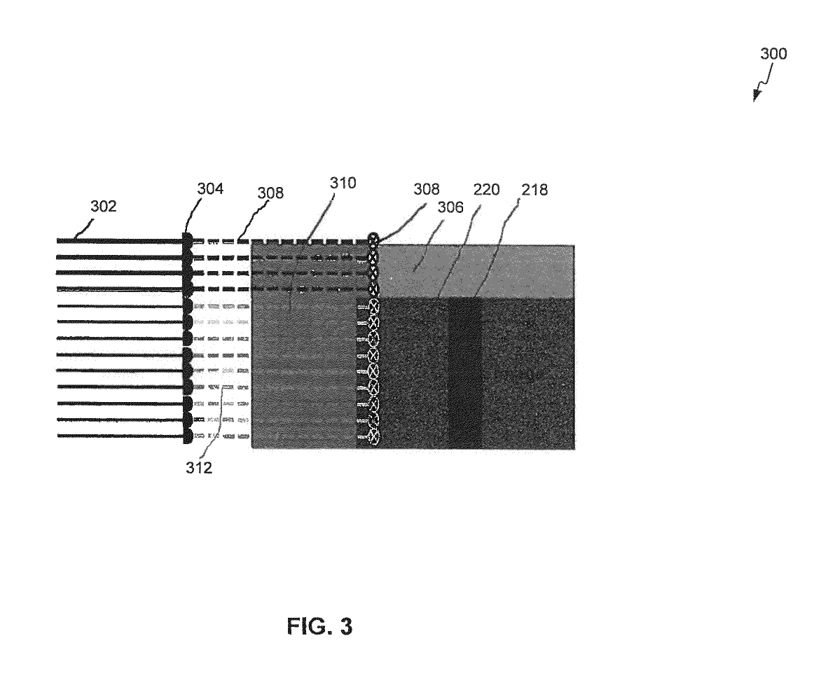

FIG. 3 illustrates a top-down view of an embodiment system 300 as described above with reference to FIG. 2. In this embodiment, parallel beams 302 can be modulated individually. An array of lenses 304 can be used to direct beams 302 to the reticle 306 via a minor (not shown). During exposure, the beam 218 heats the reticle by being partly absorbed in the chrome 220 layer of the reticle.

In a system 300 such as that illustrate in FIG. 3 beams can be individually controlled so that IR beams 308 are turned on to illuminate areas 306 outside of the chrome layer 220 and are turned off in areas 310 and 312 over the chrome layer 220. In this way, only the areas 306 outside the image will be exposed by the IR light and will be heated as a result.

The intensity of the IR light can be chosen and controlled by a controller (not shown) in order that the amount of heating outside the exposure area is the same as the heating inside the pattern area as a result of the 193 nm exposure beam 218, for example.

An array of thermal sensors can be configured to monitor the temperature of each point on the reticle, either during exposure, or in between exposures. Information provided by these thermal measurements can be used to control the intensity of each IR beam to accurately correct for thermal gradients by a laser controller (not shown).

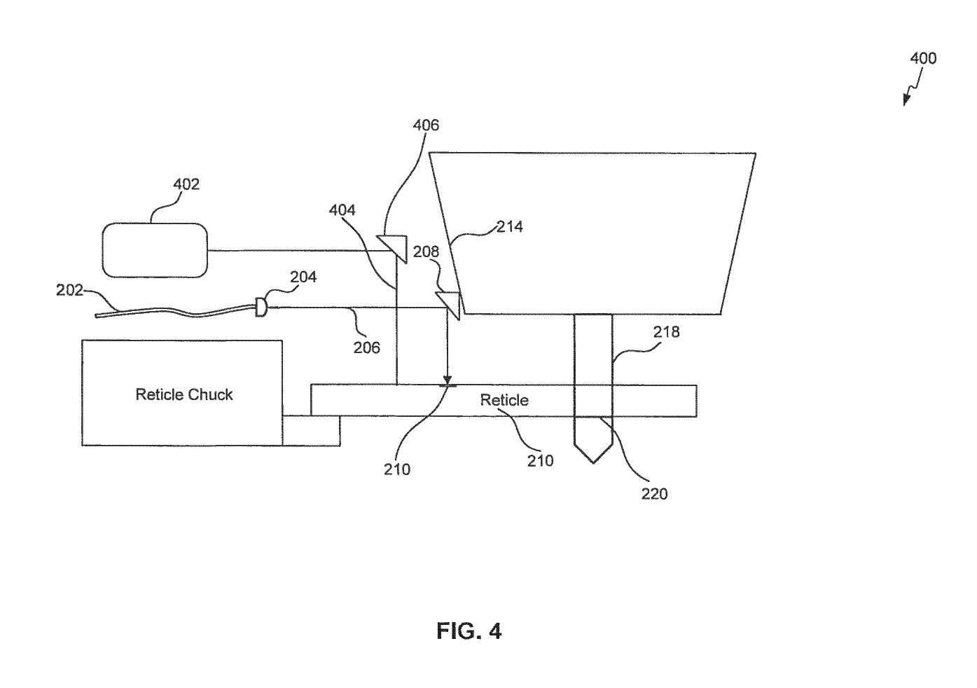

FIG. 4 illustrates a further example system 400 including an array of thermal sensors 402. In this embodiment, the array of thermal sensors 402 monitors temperature of reticle 210 based on light 404 reflected from the reticle surface via mirror 406. In this embodiment, the thermal sensors are positioned so that IR light 206 used to heat the reticle does not reach the sensor 402.

The IR lasers used for heating can be controlled (e.g., modulated and synchronized) with the sensors via the control system. Alternatively, the sensors can be activated only when the IR heating lasers are not on. A feedback loop (not shown) can be provided to coordinate the IR lasers and sensors during scanning.

In further embodiments, cooling mechanisms can be provided (e.g., an “air-shower”) to remove heat. The use of such a cooling mechanism can be employed to ensure that the final temperature of the reticle is not too high.

In a further embodiment, a reticle “pre-heater” can be employed to imprint the reticle with an initial thermal profile (or “fingerprint”). This can be done by loading the reticle on a dummy stage to create an environment that mimics heat loss from the reticle on the stage. The reticle can then be heated with a 2D heater that has a spatial distribution of heating elements that is programmable in x and y to create a spatial temperature profile. The thermal profile can be chosen to correspond to the temperature pattern that will result from exposure. Once heated, the reticle can then be transported to the reticle stage within a short time (e.g., within 60 seconds). This may result in small shifts of the heat inside the reticle. Once exposure starts, however, the thermal pattern will remain stable (since the thermal profile was chosen to correspond to the steady state heat pattern that results due to exposure). Using this approach, a thermal distribution can be established that is constant in time, thus eliminating the need for complex correction mechanisms such as those including scanning lens elements.

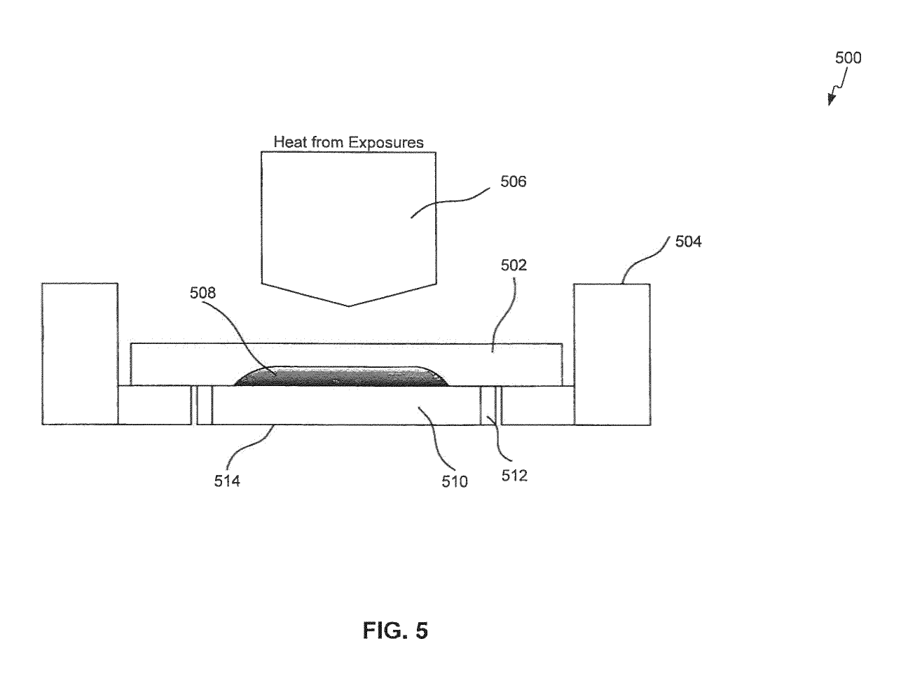

FIG. 5 schematically illustrates the reticle 502 on the reticle stage during exposure with the resulting development of a thermal profile 508. Reticle 502 is positioned on chuck 504, and exposure light 506 heats the reticle at the chrome pattern. This results in heating of the reticle. The volume 510 enclosed by pellicle frame 512 and pellicle 514 are also heated.

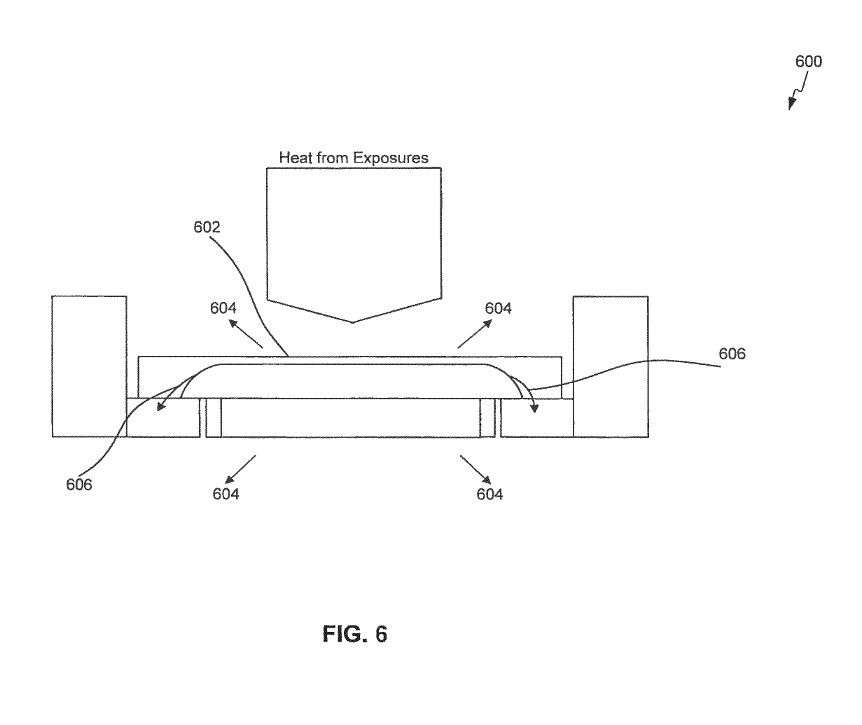

FIG. 6 shows the steady state situation 600 that arises after a long period of exposing the reticle. The heat 602 generated by exposure diffuses through the reticle. Radiation and convection 604 results in removing heat from the reticle. Some heat 606 may also flow through the clamp. Heat influx will be balanced by the heat flux leaving the system. The resulting thermal distribution in the reticle generally will not change appreciably at consecutive exposures.

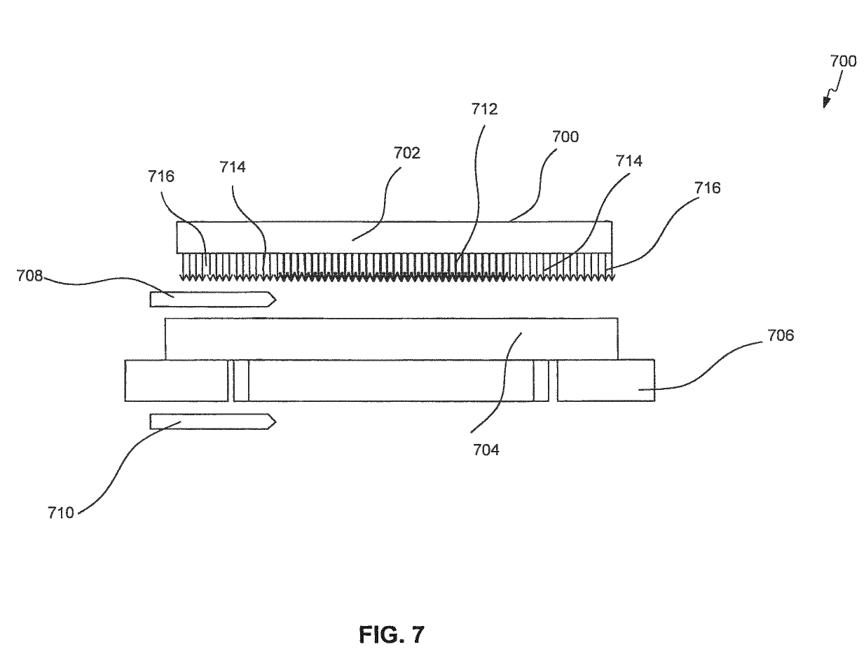

FIG. 7 illustrates an example pre-heater 700 located above the reticle (on the reticle head or “Turret”). Pre-heater 700 includes a heater 702 located above reticle 704. In this example, the reticle rests on dummy clamps 706. The main purpose of these clamps is approximate the heat conductivity the reticle will experience in a real reticle stage clamp. Airflows 708 and 710 above and below the reticle mimic flows that a reticle experiences during exposure on the reticle stage. These air flows contribute to simulating the environment of the reticle stage during exposure.

The heater 702 includes a 2D light array, producing a wavelength of roughly 193 nm (e.g., 240 nm LED). Light of such wavelengths can be absorbed by the chrome pattern. Alternatively, IR LED's or lasers can be used to create a 2D thermal pattern. IR radiation of 2 micron wavelength is absorbed directly in quartz. With such absorption, heat can be absorbed on the top of the reticle, as well as at the chrome pattern. This approach is advantageous in that no assumptions need to be made regarding the spatial distribution of the chrome patterns.

The heater 702 can be configured to produce a spatially dependent heat pattern by controlling the intensity of individual light sources. Intensities 714 and 716 can be chosen to be lower than intensity 712 above the image area. This allows heat to be introduced directly into the reticle where needed rather than waiting (for potentially long time) for the heat to diffuse from the image area into the surrounding areas outside of the exposure area.

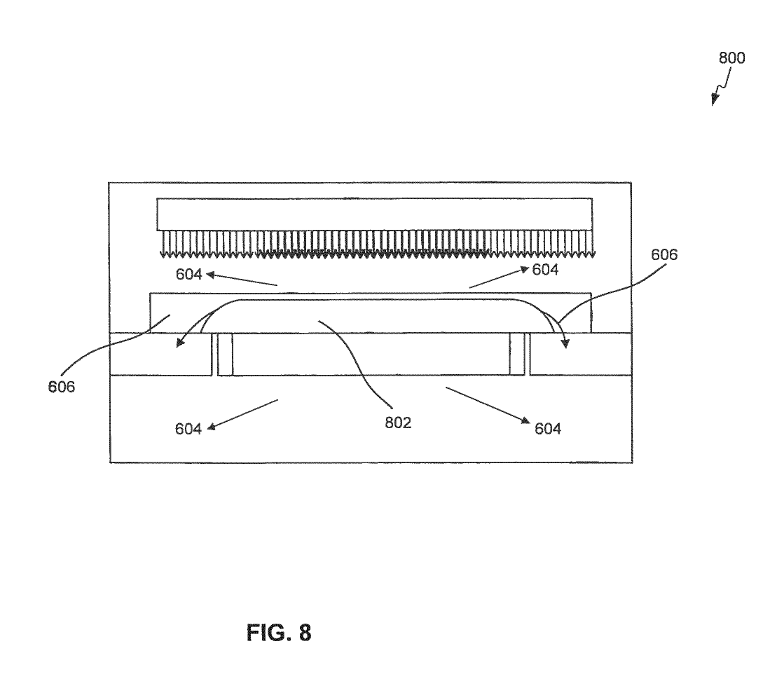

FIG. 8 illustrates the state 800 of the reticle in the pre-heater after thermal equilibrium has been established. After some heating, a thermal profile 802 in the reticle can be established that closely corresponds to that which would develop after a long period of exposure with a balanced heat flux into and out of the reticle.

The desired thermal profile can be determined through measurements, calibration, and modeling. Required corrections to the reticle pattern resulting from the imposed temperature profile can also be determined through measurements, calibration, and modeling. A theoretical model can include measured optical properties of the reticle as input. Such optical properties can include measured absorption and transmission of light obtained by scanning the reticle with a small image area and spot sensor.

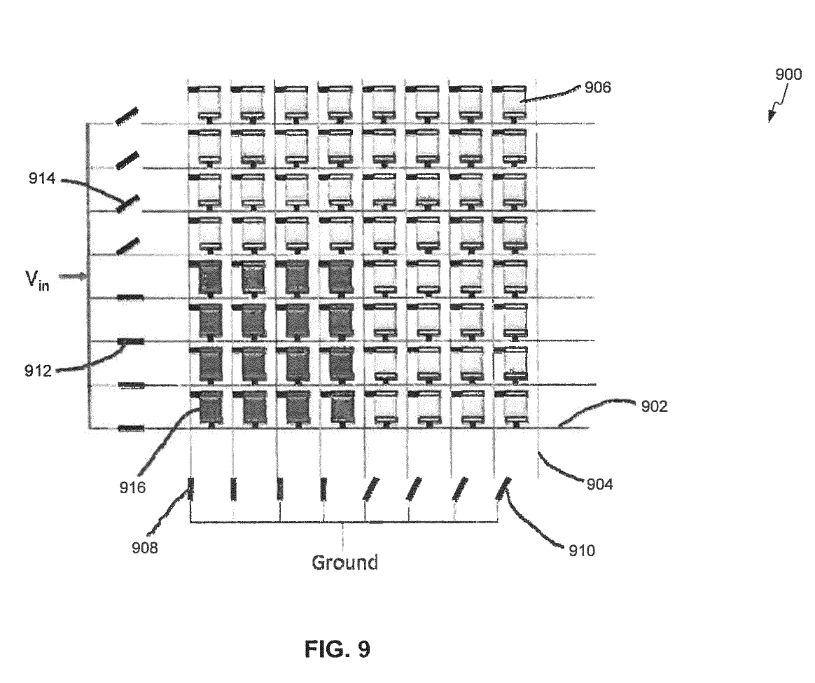

FIG. 9 illustrates a further embodiment 900 including a spatial distribution of thermal heaters. In this example, the heaters could be resistive elements. In this embodiment, a plate (e.g., a PCB board) can contain horizontal 902 and vertical 904 interconnects at equal distances. Small surface mount resistors 906 can be connected each to one of the vertical 904, and to one of the horizontal 902 interconnects. All vertical interconnects can be connected to one side of a voltage supply, and can be switched individually on 908 or off 910.

Similarly the horizontal lines can be switched on 912 and off 914. This heater array can be placed above the reticle that needs to be pre-heated. Since reticle image patterns typically have rectangular of shape, it is simply a matter of selecting the proper group of horizontal and vertical interconnects to be connected to a power supply in order to generate a desired thermal pattern. In this way, a low resolution ‘heat image’ can be generated. In FIG. 9, the bottom left part of the heater is ‘on’, and the rest is ‘off’, so only the part above the ‘hot’ resistors (lower left rectangular area 916) will be heated. With such a simple scheme, a rectangular image area can be heated uniformly.

Such embodiments are expected to be robust, since resistors typically have a long life. Even if a few resisters fail, causing a thermal ‘hole’, however, the result will not be a significant problem. The thermal time constant related to compensating for the resulting ‘hole’ is very short, so the net result in the end can be ignored. The system can, of course, be made more reliable by using two (or more) resistors in parallel per node, so if one breaks, half of the heat source would still remain.

A control system for embodiments disclosed herein is fairly straightforward to implement. One or more drivers can be used, and the switches can be implemented with standard digital logic, as would become apparent to a person having ordinary skill in the art.

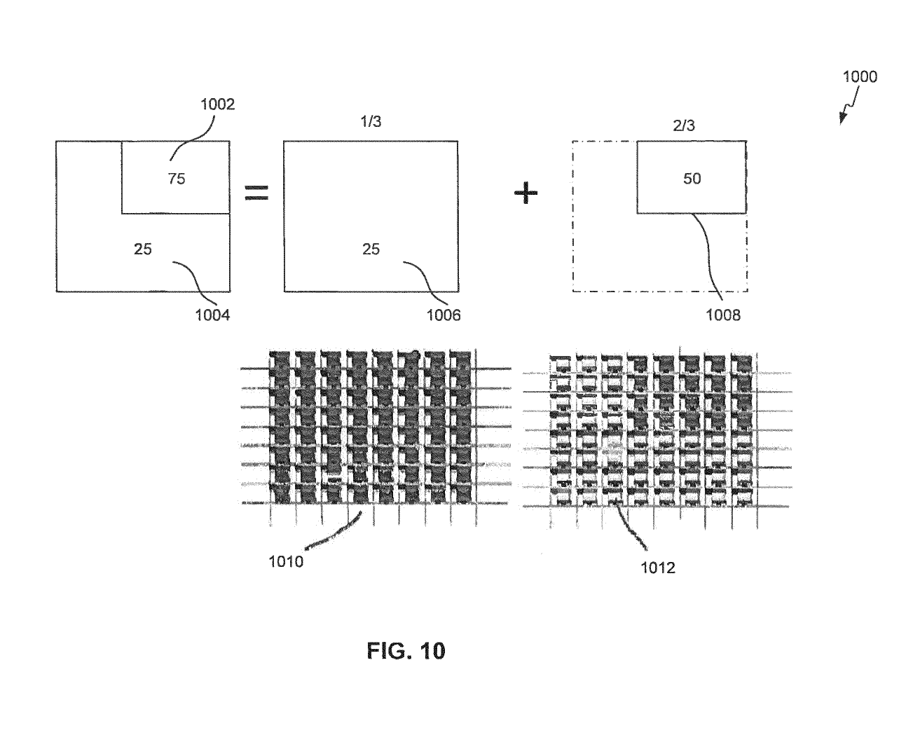

FIG. 10 illustrates the development of a complex thermal profile using a system such as the heater array of FIG. 9. For example, suppose a particular reticle has non-uniform optical properties (i.e., transmission and absorption). FIG. 10 shows a situation 1000 in which a reticle has an area 1002 (top right) that has 75% absorption as well as a remaining area 1004 that has 25% absorption. In this example, the area 1002 will experience three times the heat absorption as area 1004. This non-uniform heating profile can be compensated by using multiplexing multiple ‘heat images’ 1006 and 1008. In this example, heat image 1006 can be switched on ⅓ of the time, and heat image 1008 is switched on ⅔ of the time. The corresponding thermal resistor array patterns are illustrated schematically by 1010 and 1012 respectively.

More elaborate patterns can be generated by dividing the array into more rectangular patterns. A further embodiment could include a driver per resistor, as is done in an LCD display. A further advantage of such embodiments relates to the placement of edges which need not have high precision. Low resolutions are sufficient because high-spatial-frequency errors (arising, for example, due to a missing resister) will diffuse with small time constants.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion,” respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography, a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The terms “radiation” and “beam” used herein encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens,” where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g., semiconductor memory, magnetic or optical disk) having such a computer program stored therein.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

What is claimed is:

1. A heating system, comprising:
a pre-heater to imprint a patterning device with a temperature profile;
a plurality of radiation sources configured to generate a plurality of radiation beams to heat the patterning device during exposure of the patterning device; and
a controller to modulate intensity of radiation from the plurality of radiation sources in at least one of time and a plane substantially perpendicular to the radiation beam in operational use of the patterning device for producing a desired heat pattern in the patterning device by maintaining the temperature profile constant across the patterning device during exposure of the patterning device.

2. The system of claim 1, wherein the plurality of radiation sources comprise infra-red lasers.

3. The system of claim 1, wherein selected sources from the plurality of radiation sources are individually controllable.

4. The system of claim 1, further comprising:
a plurality of optical systems configured to receive the respective radiation beams from the sources and to deliver the radiation beams to the patterning device; and
an array of thermal sensors to determine a temperature distribution of the patterning device.

5. The system of claim 4, further comprising:
a control system comprising at least one of a feed-forward and feedback system,
wherein the control system is configured to control the operation of the thermal sensors and radiation sources so as to control the spatial temperature distribution of the patterning device.

6. The system of claim 1, wherein the plurality of radiation sources are configured to deliver beams of radiation in the form of a two-dimensional spatial distribution.

7. The system of claim 6, wherein the two-dimensional distribution is configured to deliver radiation only to areas external to a chrome pattern on the patterning device.

8. A resistive based heating system, comprising:
a plurality of resistive heating sources each configured to generate heat in response to an applied voltage or current and to deliver the heat to a patterning device at least one of prior to exposing the patterning device and during exposure of the patterning device; and
a control system configured to provide a current and/or voltage to at least one of the resistive heating sources,
wherein the control system to modulate intensity of radiation from the plurality of resistive heating sources in at least one of time and a plane substantially perpendicular to the radiation beam in operational use of the patterning device for producing a desired heat pattern in the patterning device by maintaining a constant temperature profile across the patterning device.

9. The system of claim 8, wherein each of the plurality of resistive heating sources comprise one or more resistors connected to a voltage or current source.

10. The system of claim 8, wherein selected sources from the plurality of resistive heating sources are individually controllable.

11. The system of claim 8, further comprising an array of thermal sensors configured to determine a temperature distribution of the patterning device.

12. The system of claim 11, wherein:
the control system comprising at least one of a feed-forward and feedback system,
wherein the control system is configured to control the operation of the thermal sensors and resistive heating sources so as to control the spatial temperature distribution of the patterning device.

13. The system of claim 12, wherein the control system is configured to control the spatial temperature distribution of the patterning device so as to approximate a steady state temperature distribution that would be obtained by the reticle in the presence of exposure light.

14. The system of claim 8, wherein the plurality of resistive heating sources are configured to deliver heat in the form of a two-dimensional distribution.

15. The system of claim 14, wherein the two-dimensional distribution is configured to deliver radiation only to areas external to a chrome pattern on the patterning device.

16. A lithographic apparatus, comprising:
an illumination system configured to condition a radiation beam;
a support constructed to support a patterning device, the patterning device being configured to impart the radiation beam with a pattern in its cross-section to form a patterned radiation beam;
a first heating device configured to introduce a spatially dependent heating profile to the patterning device before loading the patterning device on to the support for exposure;
a second heating device configured to maintain the heating profile constant across the patterning device during exposure of the patterning device;
a substrate table constructed to hold a substrate; and
a projection system configured to project the patterned radiation beam onto a target portion of the substrate.

17. A method of heating a patterning device, comprising:
directing a plurality of radiation beams to a patterning device;
delivering heat to the patterning device before loading the patterning device for exposure and during exposure of the patterning device; and
modulating intensity of radiation from the plurality of radiation beams in at least one of time and a plane substantially perpendicular to the radiation beam in operational use of the patterning device for producing a desired heat pattern in the patterning device by maintaining a temperature profile constant across the patterning device during exposure of the patterning device.

18. The method of claim 17, further comprising:
measuring a spatial temperature distribution of the patterning device; and
controlling the radiation beams so as to impose a specified spatial temperature distribution of the patterning device.

19. A method of heating a patterning device, comprising:
bringing a plurality of resistive heating sources into close proximity to a patterning device;
providing a current and/or voltage to at least one of the resistive heating sources so as to generate heat; and
modulating intensity of radiation from the plurality of resistive heating sources in at least one of time and a plane substantially perpendicular to the radiation beam in operational use of the patterning device for producing a desired heat pattern in the patterning device by maintaining a constant temperature profile across the patterning device.

20. The method of claim 19, further comprising:
measuring a spatial temperature distribution of the patterning device; and
controlling the resistive heating sources so as to impose a specified spatial temperature distribution of the patterning device.

21. The system of claim 4, wherein the controller is configured to change the intensity of the radiation of the plurality of radiation sources based on at least one of the sensed thermal distribution of the patterning device and a thermal pattern in which the heat flux into and out of the patterning device reaches a balance.

22. The system of claim 11, wherein the control system is configured to change the intensity of the radiation of the plurality of radiation sources based on at least one of the sensed thermal distribution of the patterning device and a thermal pattern in which the heat flux into and out of the patterning device reaches a balance.

23. The method of claim 8, further comprising:
periodically unclamping the patterning device to release the stress therefrom.

24. The method of claim 23, further comprising:
re-clamping the patterning device after patterning a wafer; and
re-aligning the patterning device if needed.
